(19) United States
(12) Patent Application Publication
(10) Pub. No.: US 2004/0175866 A1
(43) Pub. Date: Sep. 9, 2004

(54) Plastic housing comprising several semiconductor chips and a wiring modification plate, and method for producing the plastic housing in an injection-molding mold

(76) Inventors: Andreas Woerz, Kehlheim (DE); Thomas Zeiler, Regensburg (DE)

Correspondence Address: EDELL, SHAPIRO, FINNAN & LYTLE, LLC, 1901 RESEARCH BOULEVARD, SUITE 400, ROCKVILLE, MD, 20850, US

(21) Appl. No.: 10/478,682

(22) PCT Filed: Jun. 5, 2002
(86) PCT No.: PCT/DE02/02044

(30) Foreign Application Priority Data
Jun. 5, 2001 (DE) 101 27 009.7

(51) Int. Cl. H01L 21/44

(52) U.S. Cl. 438/127

(57) ABSTRACT

The invention relates to a plastic package (14) with a plurality of semiconductor chips (3) and also a wiring board (11), on which the semiconductor chips (3) are arranged, and to an injection mold for producing the plastic package (14) and also to an electronic component which can be produced with the aid of the combination of the injection mold, wiring board (11) and plastic package (14). Furthermore, the invention relates to a method which, using the wiring board (11) according to the invention and the two-part injection mold, makes it possible to produce a plastic package (14) of this type with a plurality of semiconductor chips (3) for a plurality of electronic components.

Plastic package with a plurality of semiconductor chips and a wiring board and also a method of producing the plastic package in an injection mold

The invention relates to a plastic package with a plurality of semiconductor chips and a wiring board and also to a method of producing the plastic package by means of an injection mold according to the preambles of the independent claims.

To rationalize the operation of packaging semiconductor chips, in particular semiconductor chips with a wiring board, the technique of packaging individual semiconductor chips is being abandoned in favor of techniques involving packaging in plastic packages a plurality of semiconductor chips arranged in a common package. However, the wiring boards prevent efficient and commercially advantageous embedding of the semiconductor chips on the upper side of the wiring board and the bonding channels on the underside of the wiring board, especially since the areas of the wiring board which are to receive external contacts on the underside of the wiring board are to be kept free from plastic.

The object of the invention is to specify a plastic package with a plurality of semiconductor chips on a wiring board which can be produced cost-effectively with a special injection mold.

This object is achieved by the subject matter of the independent claims. Advantageous developments of the invention emerge from the dependent claims.

According to the invention, a plurality of semiconductor chips are arranged in rows and columns in the plastic package, the semiconductor chips having active upper sides and passive rear sides and also edge sides. The active upper sides of the semiconductor chips are arranged on an upper side of a wiring board. The wiring board has bonding channels from the upper side to the underside of the wiring board.

In the case of this plastic package, the bonding channels are arranged on the underside of the wiring board one behind the other in columns. A plastic package molding compound covers the upper side of the wiring board and at least the edge sides of the semiconductor chips. The underside of the plastic package comprises the underside of the wiring board with output contact areas and strip-shaped bonding channel coverings arranged in columns. The bonding channel coverings protrude beyond the underside of the wiring board, but do not project as far from the underside of the wiring board as the external contacts to be applied. Consequently, in this embodiment of the plastic package the bonding channel coverings perform an additional function on the underside of the wiring board, in that they define the distance from a printed circuit board or some other stacked electronic component when the electronic component is soldered onto the plastic package according to the invention.

A further advantage of the plastic package is constituted by the strip-shaped bonding channel coverings arranged in columns, which protrude beyond the underside of the wiring board and have at their ends a three-dimensional plastic connection to the upper side of the plastic package. This three-dimensional plastic connection at the ends of the strip-shaped bonding channel coverings has the advantage that the material of the bonding channel coverings can consist of the same plastic molding compound as the upper side of the plastic package. Without these strip-shaped elongate bonding channel coverings, the package would have to be produced in two complex method steps, on the one hand for covering the upper side of the wiring board and on the other hand for covering the bonding channel openings on the underside of the covering films. With this embodiment of the plastic package, however, the elongate strip-shaped bonding channel coverings on the underside can be formed in one method step during the injection of the plastic molding compound from the upper side of the plastic package.

One embodiment of the invention provides that the wiring board has on its upper side an insulating layer toward the semiconductor chips and on its underside contact terminal areas, wiring lines and output contact areas for external contacts. In this case, the metal structure of the underside comprising contact terminal areas, wiring lines and output contact areas for external contacts may be laminated onto the insulating layer, so that the insulating layer forms the actually load-bearing substrate of the wiring board. The contact terminal areas on the underside of the wiring board are also referred to as bonding fingers, because bonding wires of contact areas of the active upper side of the semiconductor chips establish an electrical connection in the bonding channel to the contact terminal areas or bonding fingers on the underside of the wiring board. Finally, from the contact terminal areas or bonding fingers, wiring lines lead to individual output contact areas to which the external contacts can be applied.

For this purpose, in a further embodiment of the invention, the output contact areas are surrounded by a solder resist layer, which covers in particular the wiring lines, in order that they are not damaged or coated with external contact material when the external contacts are attached, the external contacts protruding further out from the underside of the wiring board than the bonding channel coverings.

In a further embodiment of the invention, the elongate and strip-shaped bonding channel coverings embed connecting lines between the contact areas on the active upper side of the semiconductor chip and contact terminal areas on the underside of the wiring board in a package plastic molding compound. During the packaging in plastic, this package plastic molding compound is led at the ends of the strip-shaped bonding channel coverings from the upper side of the plastic package to the bonding channels arranged on the underside of the wiring board.

On the upper side of the plastic package, in addition to the side edges of the semiconductor chips arranged in rows and columns, the passive rear side of the semiconductor chips may also be covered with the package plastic molding compound of the plastic package. Consequently, although the thickness of the plastic package is increased, at the same time the semiconductor chips are better protected against impact or other adverse effects than if the passive rear sides of the semiconductor chips simultaneously form part of the upper side of the plastic package.

In a further embodiment of the invention, the external contacts in the external contact regions of the underside of the wiring board are also arranged in rows and columns and are free from package plastic molding compound. These rows and columns of the external contact regions have a standardized pitch, which in the case of BGA packages (Ball Grid Arrays) goes down to a pitch of as little as 0.8 mm and in the case of fine structures of the external contacts is even lower.

In a further embodiment of the invention, the wiring board has on its underside in the external contact regions solder balls or contact bumps, which are arranged on the output contact areas. While the solder balls become contact bumps of solder material during soldering onto the output contact areas, the contact bumps may also consist of superficially metallized plastic and take any desired forms.

For the production of a plastic package of this type, which has a plurality of semiconductor chips arranged in rows and columns and arranged on a wiring board, the wiring board has through-openings from the upper side of the wiring board to each strip-shaped bonding channel covering, arranged in columns, on the underside of the wiring board.

In a further embodiment of the invention, these through-openings are dimensioned in such a way that they represent constrictions for the liquid package plastic molding compound. These constrictions advantageously prevent the strip of bonding channel coverings from being filled with plastic molding compound in an uncontrolled way, since they represent a flow resistance for the plastic, so that initially the upper side of the package can be coated with plastic molding compound under full injection pressure and only then, with a great delay, can the plastic spread via the constrictions into the bonding channels or the strips for bonding channel coverings.

For this purpose, in a further embodiment of the invention, the constrictions on the upper side of the wiring board are arranged in a region which is wetted last by the liquid package plastic molding compound on the upper side during the production of the plastic package. This has the advantage that only after complete wetting of the upper side of the plastic package with package plastic molding compound can this plastic molding compound penetrate into the bonding channel strips via the constrictions.

The plastic package according to the invention can also be separated into individual electronic components, in that the plastic package is sawn into rows and columns. In this case, not only is the plastic molding compound sawn into individual pieces, but the wiring board is also separated into the regions belonging to the respective semiconductor chip. An electronic component of this type differs from conventional components in that it has in packaged form sawn outer edges, which advantageously allow a highly precise outer dimension of the electronic components.

In a further preferred embodiment of the invention, the external contact regions have external contacts arranged in rows and columns. This arrangement can meet international standards with internationally fixed pitches, so that the semiconductor chips are suitable for inclusion on standardized printed circuit boards.

For producing a plastic package according to the invention, a novel injection mold is created, the plastic package having semiconductor chips arranged in a plurality of rows and columns. The upper side of the plastic package is formed by an upper-side mold of the injection mold, which rests on the upper side of the wiring board with a sealing sleeve and has an injection hopper, via which the package plastic molding compound is forced with an injection pressure onto the upper side of the wiring board and at least to the side edges of the semiconductor chips.

As soon as the plastic molding compound reaches the constrictions to the bonding channels on the underside, it is forced through these constrictions and forms the strip-shaped bonding channel coverings on the underside of the wiring board. For this purpose, provided on the underside is an underside mold of the injection mold, which surrounds the bonding channel regions with sealing ribs and has at the end of each bonding channel region a venting bore, so that the package plastic molding compound is initially injected onto the upper side and is led via the constrictions to the strip-shaped bonding channel coverings, while the air accumulated in the cavities is forced out via the venting bore at the end of the underside mold.

Since the upper side of the plastic package is packaged over a large surface area with the aid of the injection molding technique, a high pressure develops, which can lead to warpage of the wiring board, for which reason, in addition to the sealing ribs which surround the bonding channel regions, supporting ribs intended to support the wiring board in the remaining regions are provided for the underside mold of the injection mold. What is more, for the underside mold, a supporting rib is provided opposite the sealing sleeve of the upper-side mold.

A method of producing a plastic package of the present invention, which has a plurality of semiconductor chips which are arranged in rows and columns and are arranged on a wiring board, has the following method steps:

preparation of a wiring board with semiconductor chip positions arranged in rows and columns and sawing track regions provided in between and also with at least one bonding channel, arranged on each semiconductor chip position, and with a constriction for the three-dimensional connection of the upper side and underside of the wiring board,

application of semiconductor chips to the semiconductor chip positions, with contact areas of the active upper side of the semiconductor chips being arranged in the region of the bonding channels,

establishment of bonding connections between the contact areas and wiring lines on the underside of the wiring board in the region of the bonding channels,

simultaneous placement of the upper-side mold and the underside mold of an injection mold, with sealing off of an upper-side cavity for the production of the upper side of the plastic package and underside cavities for the production of bonding channel coverings,

injection of package plastic molding compound via an injection hopper of the upper-side mold and spreading of the package plastic molding compound via constrictions into the underside cavities.

This method has the advantage that both the upper side of the plastic package and the bonding channel coverings on the underside of the injection-molded package are produced in a single injection-molding step, which lowers the cost of the process of packaging semiconductor chips arranged in columns and rows. After the curing of the plastic package in the injection mold, it can be removed from the injection mold and the plastic package with a plurality of semiconductor chips arranged in rows and columns can be separated along the provided sawing tracks into individual electronic components. In the case of this method, sawn side edges are produced, giving the electronic components their characteristic and precise outer form.

In the case of a preferred example of how the method of producing a plastic package is implemented, the package plastic molding compound is injected under a pressure of 8-15 MPa via an injection hopper. In this method step, initially a high pressure is exerted on the upper side of the wiring board, so that there is the risk of the wiring board becoming warped, since the injection pressure acts on the wiring board only from one side. Only when the liquid package plastic molding compound reaches the through-openings for the bonding channel coverings on the underside of the wiring board is a counterpressure produced in partial regions of the underside, that is wherever the elongate bonding channel covering is created. To avoid warping of the wiring board also in the injection phase and to keep the output contact areas of the wiring board free from plastic molding compound on the underside, provided on the underside mold are supporting ribs, which on the one hand are arranged opposite the sealing sleeve on the upper side and on the other hand are additionally arranged between the elongate bonding channel coverings.

The venting bores in the underside mold at the end of the bonding channel covering cavities ensure that no air cushions or voids are enclosed in the package plastic molding compound. Furthermore, they ensure that the entire bonding channel covering on the underside of the plastic package can be filled with plastic molding compound.

In the case of semiconductor packages with a protection of the rear sides of the semiconductor chip, problems arise if bonding channel coverings are to be simultaneously produced on the active upper side of the semiconductor chips. The aim of the invention is to work on both sides of a substrate or a wiring board with cavities of different sizes of an injection mold. The problems arise with different cavities on either side of the wiring board as a result of the different surface-area loading between the upper side and the underside of the wiring board, since the smaller cavity on the underside cannot absorb the loads of the larger surface area of the cavity on the upper side.

This difficulty is exacerbated if the arrangement has a matrix of external contacts or a Matrix Array Package (MAP). To overcome this difficulty, a two-step process can be used, in that initially, in a first method step, the bonding channel is printed on and subsequently, in a second method step, a plastic molding compound is applied on the semiconductor-chip side. A further possibility would be firstly, in a first method step, to fill the bonding channel with a plastic molding compound and subsequently, in a second step, to machine the semiconductor-chip side. Finally, it is also possible to accomplish encapsulation with the aid of a film, in that the film is arranged between the semiconductor chip and the mold. The film then presses the semiconductor chip onto the wiring board and the wiring board then presses onto the seal for the cavity on the bonding-channel side.

These possible solutions to the above difficulties have the disadvantage, however, of a two-stage process and possibly difficulties with the tolerances of the semiconductor chip height, the loads on the semiconductor chip and the exposure of the rear side of the semiconductor chip during packaging in ambient atmosphere.

In comparison with these possibilities, the present invention envisages initially clamping the wiring board or the substrate on the semiconductor-chip side right up against an injection mold, so that no plastic flows out of the injection molding cavity, and then injecting a plastic molding compound on the semiconductor-chip side of the wiring board, the semiconductor chip covering the bonding channel in such a way that no plastic reaches the rear side of the wiring board.

After filling the semiconductor-chip side, the pressure in the cavity on the semiconductor-chip side increases by provision of a constriction, which regulates the pressure at the end of the chip-side cavity.

On account of the rising pressure in the cavity on the chip side, the wiring board or the substrate is smoothly laminated with plastic molding compound, and the plastic molding compound can penetrate into the bonding channel cavity. The plastic molding compound is then forced onto the bonding-channel side via a through-opening, which is formed as a constriction. During the encapsulation of the bonding-channel side, the substrate or the wiring board is sealed off precisely on the bonding-channel side during the injection on account of the higher pressure on the larger side and the higher pressure on the side for the protection of the semiconductor chips. Vents are provided at the end of the bonding channel, so that the injection process ends there. After complete filling of the semiconductor-chip side and the bonding channel covering, the plastic injection molding compound is compressed and cured.

To sum up, the following advantages are consequently obtained:

1. Smooth sealing off of the cavities of different sizes on either side of a substrate or a wiring board.

2. Standard systems can be used for the injection, without additional materials or films being required. A MAP technique can be used.

3. In the bonding channel, no additional stresses are exerted on the semiconductor chip and the substrate or the wiring board.

4. Independence from chip size tolerances and chip adhesive heights is achieved.

5. An injection operation in a single stage or a single method step is possible, so that multistage injection-molding processes are unnecessary.

6. Both the device and the method can be used for different substrate materials or materials of the wiring board, so that both metal plates and ceramic sheets or printed circuit boards or leadframe strips of plastic can be used.

These advantages are obtained by a specially developed injection mold in combination with a correspondingly designed wiring board or a corresponding substrate. This wiring board has constrictions as through-openings for the package plastic molding compound, in order to produce a difference in pressure between the cavity on the semiconductor-chip side and the bonding channel cavities when producing plastic packages.

The invention is now explained in more detail on the basis of embodiments and examples of implementation with reference to the accompanying drawings.

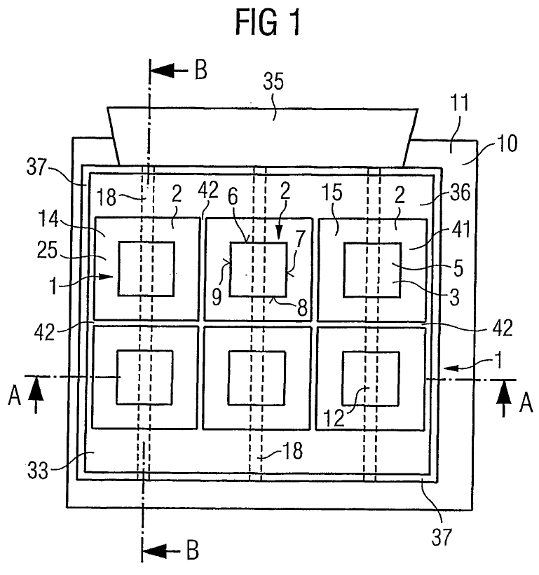

FIG. 1 shows a schematic plan view of a plastic package for a plurality of semiconductor chips,

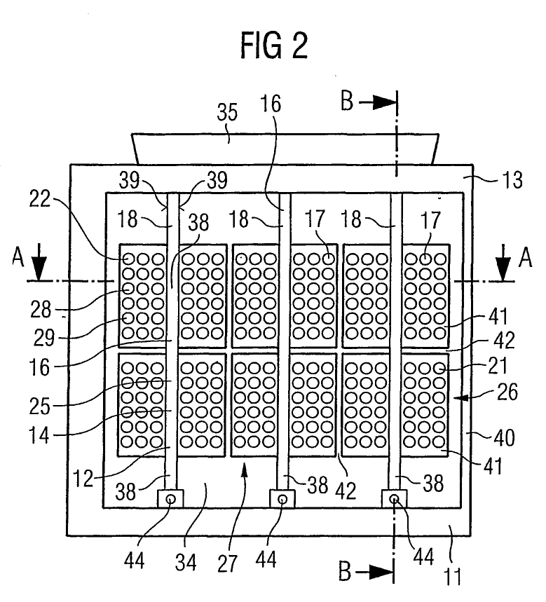

FIG. 2 shows a schematic view from below of a plastic package for a plurality of semiconductor chips,

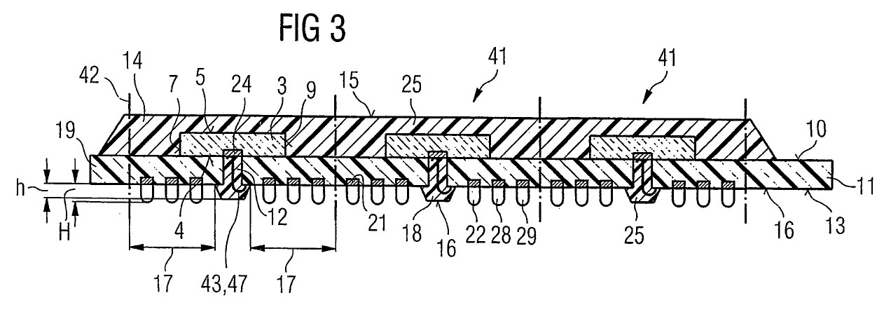

FIG. 3 shows a schematic cross section along the sectional line A-A in FIG. 1 and FIG. 2 through a plastic package with an injection mold,

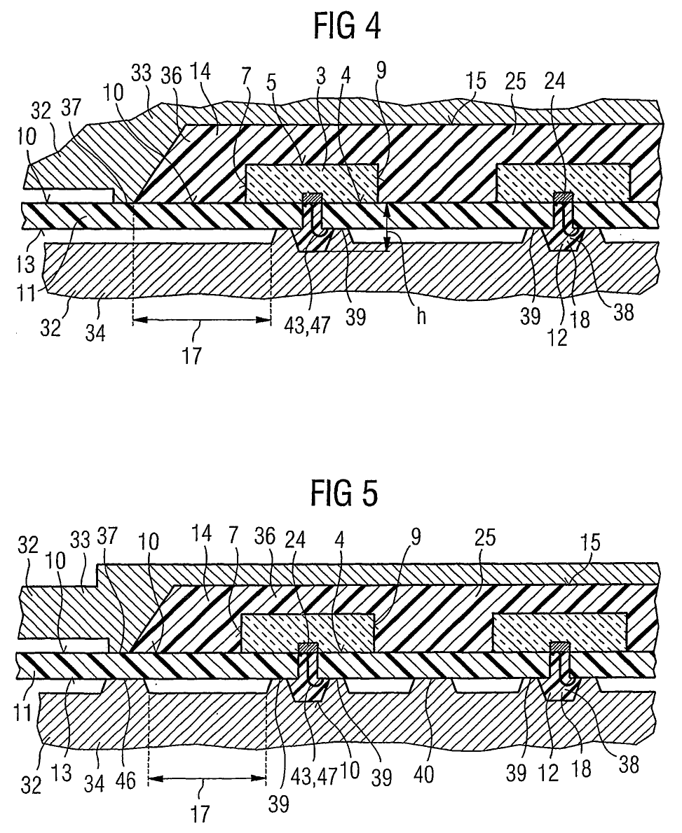

FIG. 4 shows a partial region of a schematic cross section of an injection mold along the sectional line A-A in FIG. 1 and FIG. 2 of a first embodiment of the invention,

FIG. 5 shows a partial region of a schematic cross section of an injection mold along the sectional line A-A in FIG. 1 and FIG. 2 of a second embodiment of the invention,

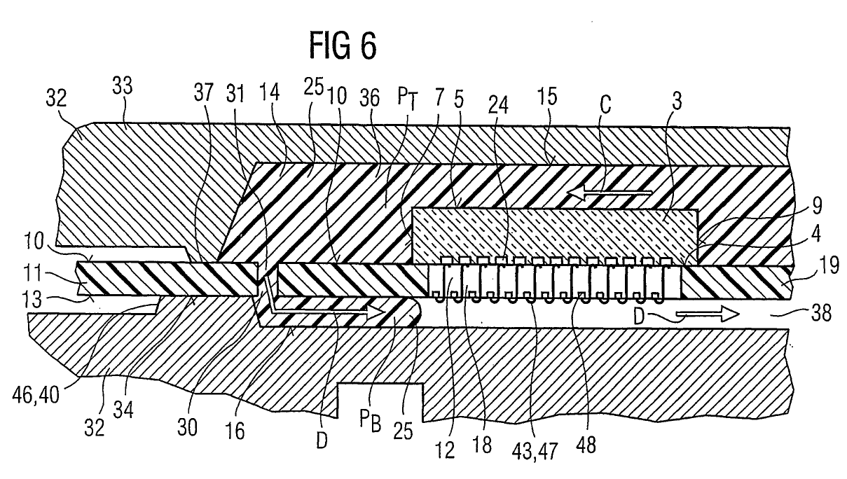

FIG. 6 shows a partial region of a schematic cross section of an injection mold along the sectional line B-B in FIG. 1 and FIG. 2.

FIG. 1 shows a schematic plan view of a plastic package 14 for a plurality of semiconductor chips 3. The reference numeral 1 designates rows of semiconductor chips and the reference numeral 2 designates columns of semiconductor chips in the plastic package 14. The reference numeral 5 designates the passive rear side of the semiconductor chips and the reference numerals 6, 7, 8, 9 designate edge sides of the semiconductor chip. The reference numeral 10 designates the upper side of a wiring board 11. The reference numeral 12 designates a bonding channel under the semiconductor chip 3. The reference numeral 18 designates bonding channel coverings, the reference numeral 25 a package plastic molding compound, the reference numeral 35 an injection hopper for the package plastic molding compound 25. The reference numeral 37 designates the region in which a sealing sleeve rests on the wiring board 11 and the reference numeral 42 designates sawing track regions for the cutting up of the plastic package 14 into electronic components 41.

The semiconductor chips 3 of the plastic package 14 are arranged in rows 1 and columns 2. In the exemplary embodiment according to FIG. 1, three semiconductor chips 3 are arranged in a row 1 and two semiconductor chips 2 are arranged in a column 2. The semiconductor chips 3 are attached on an upper side 10 of a wiring board 11. In this case, the passive rear side 5 of the semiconductor chips 3 protrudes from the plane of the drawing. In this embodiment, both the passive rear side 5 of the semiconductor chips 3 and the side edges 6, 7, 8, 9 of the semiconductor chips 3 are embedded in the package plastic molding compound 25. The active upper side of the semiconductor chips 3 is arranged on the upper side 10 of the wiring board 11. From the upper side 10 of the wiring board 11 to the underside of the wiring board 11, openings have been made into the wiring board 11 in the region of contact areas of the semiconductor chips 3. These openings are also referred to as bonding channels 18 and serve for connecting contact areas on the semiconductor chip 3 to contact terminal areas on the wiring board 11.

In the embodiment according to FIG. 1, the bonding channels 12 on the underside of the wiring board 11 are covered by elongate bonding channel coverings 18, which are arranged in columns and are represented by dashed lines. In this embodiment of the invention, the upper side 15 of the plastic package 14 reaches as far as the peripheral sealing sleeve 37 and forms a planar upper side 15 of the plastic package 14 for all the semiconductor chips 3.

A plastic package 14 of this type can be sawn up after completion, the possible sawing tracks 42 already being depicted in the embodiment of FIG. 1. In FIG. 1, the injection hopper 35 on the upper side 15 of the plastic housing 14 can also be seen.

During the production of the plastic package 14, firstly the upper side 15 of the plastic package 14 is produced via the injection hopper 35 under a pressure of 8-15 MPa. After filling an upper-side cavity of the injection mold, the package plastic molding compound flows through special through-openings between the upper side 10 of the wiring board 11 and the underside of the wiring board 11 into the provided cavities of an underside mold for the production of the elongate bonding channel coverings 18. Consequently, after this production step, on the one hand the upper side 15 of the plastic package 14 is completely filled with plastic molding compound and on the other hand the underside of the electronic components is provided with an elongate bonding channel covering 18 of package plastic molding compound 25 only in the region of the bonding channels 12. It is decisive here that no plastic molding compound is applied on the underside outside the bonding channel coverings 18, since, alongside the bonding channel coverings 18, output contact areas of a metal are to be kept free for the external contacts of the electronic components.

FIG. 2 shows a schematic view from below of a plastic package 14 for a plurality of semiconductor chips 3. Components with the same functions as in FIG. 1 are designated by the same reference numerals and are not separately explained. The underside 16 of the plastic package 14 shows the elongate bonding channel coverings 18 arranged in columns that are characteristic of the invention. Of the entire plastic package 14, on the underside only these bonding channel coverings 18 are produced from a package plastic molding compound 25. The package plastic molding compound 25 penetrates via the coupling regions 44 at the beginning of each bonding channel covering 18 from the upper side 10 of the wiring board 11 to the underside 13 of the wiring board 11 and, from there, fills the bonding channel openings 12, arranged one behind the other in columns, under the individual semiconductor chips with package plastic molding compound 25, so that the bonding connections arranged in the bonding channels 12 are embedded in plastic package molding compound 25 and protected from damage.

In addition, FIG. 2 shows an arrangement of output contact areas 21 or external contacts 22, which are arranged in rows 26 and columns 27 on the output contact areas 21. In this exemplary embodiment of FIG. 2, six rows 26 and six columns 27 of the external contacts 22 belong to each bonding channel 12 of a semiconductor chip 3. The external contacts 22 are connected via wiring lines to contact terminal areas or bonding fingers, which are arranged along each bonding channel 12, bonding connections reaching from these contact terminal areas into the bonding channels. The bonding connections electrically connect the contact terminal areas of the wiring board 11 to contact areas on the semiconductor chip 3.

The external contacts 22 may be formed as solder balls 28 or contact bumps 29. The dashed line in FIG. 2 shows the contact track of a supporting rib 40, which is arranged opposite the sealing sleeve 37 shown in FIG. 1. The supporting rib 40 itself is arranged on the underside mold of the injection mold, to avoid bending of the substrate or the wiring board 11 during the injection molding.

The three bonding channel coverings 18 shown in FIG. 2 protrude only slightly beyond the underside of the electronic components 41 and have a smaller height than the solder balls 28 or contact bumps 29. In this case, the height of the bonding channel coverings 18 may serve at the same time for determining the distance when one of the electronic components 41 is attached on a printed circuit board or electronic components 41 are stacked one on top of the other. Consequently, electronic components 41 which are equipped with the continuous elongate bonding channel covering according to the invention have advantages during further processing or during the integration of the electronic components 41 in more complex circuits.

To ensure that the external contact regions 17 are not wetted or covered by plastic molding compound during the injection molding of the package plastic molding compound 25, sealing ribs 39 are provided on the underside mold 34 of the injection mold in the edge regions of the bonding channel coverings 18. The sealing ribs 39 completely surround the bonding channel covering 18.

FIG. 3 shows a schematic cross section along the sectional line A-A in FIG. 1 and FIG. 2 through a plastic package 14. Components with the same functions as in the previous figures are designated by the same reference numerals and are not separately explained. In this embodiment of the invention, a wiring board 11 or a substrate 11 carries the semiconductor chips 3, which rest with their active upper side 4 on the wiring board 11. The wiring board 11 comprises an insulating layer 19 and has on its underside 13 a structure of connecting lines. These connecting lines connect output contact areas 21, which in this embodiment of the invention carry contact bumps 29 or solder balls 28 as external contacts 22 and protrude further from the underside 13 of the wiring board 11 than the bonding channel coverings 18.

The bonding channel coverings 18 consist of the same package plastic molding compound 25 as the upper side 15 of the plastic package 14. The metallic output contact areas 21 on the structured underside 13 of the wiring board 11 are in electrical connection with contact terminal areas or bonding fingers in the region of the bonding channel coverings 18 via wiring lines. From the output contact areas or bonding fingers, a bonding connection 43 leads to microscopically small contact areas 24 on the semiconductor chip 3. In this context, ‘microscopically small’ means that the dimensions of these contact areas 24 can only be perceived and measured under an optical microscope, while the output contact areas 21 are of a macroscopic size and consequently can be seen and measured with the naked eye.

FIG. 3 shows a row with three semiconductor chips 3, the passive rear sides 5 and edge sides 6, 7, 8, 9 and 10 of which are completely embedded in the package plastic molding compound 25. Components with the same functions as in the previous figures are designated by the same reference numerals and are not separately explained. The injection molds for producing a plastic package 14 of this type with a plurality of semiconductor chips 3, which can subsequently be separated into individual electronic components along the sawing track regions 42, are shown in the further figures. In this embodiment of the invention, the bonding channel covering 18 has a smaller height h than the height H of the external contacts 22.

FIG. 4 shows a partial region of a schematic cross section of an injection mold 32 for a plastic package 14 with a plurality of semiconductor chips 3 along the sectional line A-A in FIGS. 1 and 2 of a first embodiment of the invention. Components with the same functions as in the previous figures are designated by the same reference numerals and are not separately explained. The injection mold 32 substantially comprises an upper-side mold 33 and an underside mold 34. The upper-side mold 33 has a sealing sleeve 37, which buries itself in the material of the wiring board 11 or the substrate to seal off the upper-side mold 33. The upper-side cavity 36 has a relatively large surface area in relation to the underside cavities 38, so that the injection pressure in the range of 8-15 MPa represents a high flexural loading for the wiring board 11. However, the high injection pressure in the upper-side cavity 36 ensures that the sealing ribs 39 along the bonding channel coverings 18 on the underside 13 of the wiring board 11 are reliably sealed off. As figure 4 shows, the bonding channel covering 18 ensures that the bonding connection 43 of the contact terminal area on the underside 13 of the wiring board 11 to the contact area 24 on the semiconductor chip 3 is completely embedded in the plastic material. At the same time, the bonding channel covering 18 protrudes at a height h beyond the underside 13 of the wiring board 11. However, at 80 to 250 μm, this height h is smaller than the height H shown in FIG. 3, at 300 to 600 μm, of the external contacts to be attached, so that a reliable electrical connection of the external contacts to more complex circuit configurations is possible.

FIG. 5 shows a partial region of a schematic cross section of an injection mold 32 for a plastic package 14 along the sectional line A-A in FIG. 1 and FIG. 2 of a second embodiment of the invention. Components with the same functions as in the previous figures are designated by the same reference numerals and are not separately explained. The second embodiment according to FIG. 5 differs from the first embodiment of the injection mold 32 according to FIG. 4 in that, for supporting the wiring board 11, the underside mold 34 of the injection mold has additional supporting ribs 40 and, in addition, a surrounding supporting rib 46, which is arranged opposite the sealing sleeve 37 of the upper-side mold 33, in order in this way to support the wiring board 11.

FIG. 6 shows a partial region of a schematic cross section of an injection mold 32 along the sectional line B-B in FIG. 1 and FIG. 2. Components with the same functions as in the previous figures are designated by the same reference numerals and are not separately explained. The injection mold 32 comprises an upper-side mold 33 and an underside mold 34. The sectional line B-B is positioned such that the bonding channel 12 is intersected in its longitudinal extent.

In the region of the bonding channel 12, the semiconductor chip 3 has on its active upper side 4 contact areas 24 arranged next to one another. In this embodiment, bonding wires 47 connect the contact areas 24 to contact terminal areas 48 in the edge region of the bonding channel 12 on the underside 13 of the wiring board 11. The semiconductor chip 3 is adhesively attached on the upper side 10 of the wiring board 11 and completely covers the bonding channel 12.

During the injection of package plastic molding compound 25 in the direction of the arrow C under an injection pressure P_{T} of 8-15 MPa, the injection molding compound reaches the through-opening 13 in the wiring board, which is dimensioned such that it acts as a constriction 31, and consequently a high back pressure is formed in the upper-side cavity 36 of the upper-side mold 30 and all the cavities in the upper-side cavity 36 are filled with plastic molding compound.

In this example, plastic molding compound is introduced in the direction of the arrow both at the side edges of the semiconductor chip and over the passive rear side of the semiconductor chip, so that the semiconductor chips are embedded in package plastic molding compound 25. Through the constriction 31, plastic molding compound penetrates in the direction of the arrow D to form a bonding channel covering 18 on the underside 13 of the wiring board. As soon as the package plastic molding compound 25 reaches the bonding channel 12, the bonding connections 43 are embedded in package plastic molding compound 25 under a pressure P_{B}, while the air located in the bonding channel 12 can escape from a venting bore (not shown) at the end of the bonding channel covering 18 in the underside mold 34 of the injection mold 32.

With the injection mold 32 in conjunction with the constriction 31 in the wiring board 11, it is possible to produce both the upper side of the plastic package 14 and the underside 16 of the plastic package 14 in a single injection operation via an injection hopper for the upper-side cavity 36 in one injection-molding step. At the same time, the underside mold 34 ensures that package plastic molding compound 25 is injected in the direction of arrow D onto the underside 13 of the wiring board only and exclusively for forming the bonding channel covering 18.

1. A plastic package with a plurality of semiconductor chips (3) which are arranged in rows (1) and columns (2) and have active upper sides (4) and passive rear sides (5) and edge sides (6, 7, 8, 9), the active upper sides (4) of the semiconductor chips being arranged on an upper side (10) of a wiring board (11), and the wiring board (11) having bonding channels (12) to its underside (13) and the bonding channels (12) being arranged on the underside (13) of the wiring board (11) one behind the other in columns and the plastic package (14) covering with its upper side (15) the upper side (10) of the wiring board (11) and at least the edge sides (6, 7, 8, 9) of the semiconductor chips (3) and the plastic package (14) having an underside (16), which comprises at least the underside (13) of the wiring board (11) with external contact regions (17) and strip-shaped bonding channel coverings (18) arranged in columns for the bonding channels (12).

2. The plastic package as claimed in claim 1, characterized in that the wiring board (11) has on its upper side (10) an insulating layer (19) toward the semiconductor chips (3) and on its underside (13) contact terminal areas (20), wiring lines and output contact areas (21) for external contacts (22).

3. The plastic package as claimed in claim 1 or claim 2, characterized in that the wiring lines are covered by a solder resist layer.

4. The plastic package as claimed in one of the preceding claims, characterized in that the bonding channel coverings (18) embed connecting lines (23) between contact areas (24) on the active upper side (4) of the semiconductor chip (3) and contact terminal areas (48) on the underside (13) of the wiring board (11) in a package plastic molding compound (25).

5. The plastic package as claimed in one of the preceding claims, characterized in that a package plastic molding compound (25) of the plastic package (14) is arranged on the passive rear sides (5) of the semiconductor chips (3).

6. The plastic package as claimed in one of the preceding claims, characterized in that the external contact regions (17) of the underside (13) of the wiring board (11) have external contacts (22), which are arranged in rows (26) and columns (27).

7. The plastic package as claimed in one of the preceding claims, characterized in that the wiring board (11) has on its underside (13) in the external contact regions (17) solder balls (28) or contact bumps (29), which are arranged on output contact areas (21).

8. A wiring board which is suitable for the production of a plastic package (14), the plastic package (14) having a plurality of semiconductor chips (3) which are arranged in rows (1) and columns (2) and are arranged on a wiring board (11), and the plastic package (14) covering with its upper side (15) the upper side (10) of the wiring board (11) and at least the edge sides (6, 7, 8, 9) of the semiconductor chips (3) and the plastic package (14) having an underside (16), which comprises at least the underside (13) of the wiring board (11) with external contact regions (17) and strip-shaped bonding channel coverings (18) arranged in columns for bonding channels (12) and the wiring board (11) having through-openings (30) from the upper side (10) of the wiring board (11) to each strip-shaped bonding channel covering (18) arranged in columns.

9. The wiring board (11) as claimed in claim 8, characterized in that the size of the through-opening (30) respectively corresponds to a constriction (31) for a liquid package plastic molding compound (25).

10. The wiring board (11) as claimed in claim 9, characterized in that the constriction (31) is arranged on the upper side (10) of the wiring board (11) in a region which is wetted last by the liquid package plastic molding compound (25) on the upper side (10) during the production of the plastic package (14).

11. An electronic component which is cut out from a plastic package (14), the plastic package (14) having a plurality of semiconductor chips (3) which are arranged in rows (1) and columns (2) and are arranged on a wiring board (11), and the plastic package (14) covering with its upper side (15) the upper side (10) of the wiring board (11) and at least the edge sides (6, 7, 8, 9) of the semiconductor chips (3) and the plastic package (14) having an underside (16), which comprises at least the underside (13) of the wiring board (11) with external contact regions (17) and strip-shaped bonding channel coverings (18) arranged in columns for bonding channels (12), and the electronic component (41) in each case having a semiconductor chip (3), a portion of the wiring board (11) belonging to the semiconductor chip (3) and a portion of the strip-shaped bonding channel covering (18) belonging to the semiconductor chip.

12. The electronic component as claimed in claim 11, characterized in that the external contact regions (11) have external contacts (22) arranged in rows (26) and columns (27).

13. An injection mold for producing a plastic package (14), the plastic package (14) having a plurality of semiconductor chips (3) which are arranged in rows (1) and columns (2) and are arranged on a wiring board (11), and the plastic package (14) covering with its upper side (15) the upper side (10) of the wiring board (11) and at least the edge sides (6, 7, 8, 9) of the semiconductor chips (3) and the plastic package (14) having an underside (16), which comprises at least the underside (13) of the wiring board (11) with external contact regions (17) and strip-shaped bonding channel coverings (18) arranged in columns for bonding channels (12) and the injection mold (32) having an upper-side mold (33) for the production of the upper side (15) of the plastic package and an underside mold (34) for the production of the underside (16) of the plastic package and the upper-side mold (33) having an injection hopper (35) for an upper-side cavity (36) and a sealing sleeve (37), which rests in a sealing manner on the upper side (10) of the wiring board (11), and the underside mold (34) having a plurality of underside cavities (38) with sealing ribs (39), which rest in a sealing manner on the underside (13) of the wiring board (11) and surround the strip-shaped bonding channel coverings (18), and the underside cavities (38) being three-dimensionally connected to the upper-side cavity (36) via constrictions (31) in the wiring board (11) and venting bores being arranged in the underside mold (34).

14. The injection mold as claimed in claim 13, characterized in that the venting bores are arranged in a downstream end region of the bonding channel covering (18).

15. The injection mold as claimed in claim 13 or claim 14, characterized in that the underside mold (34) has additional supporting ribs (40) in the external contact regions (17) and/or lying opposite the sealing sleeve (37) of the upper-side mold (33).

16. A method of producing a plastic package (14), the plastic package (14) having a plurality of semiconductor chips (3) which are arranged in rows (1) and columns (2) and are arranged on a wiring board (11), and the plastic package (14) covering with its upper side (15) the upper side (10) of the wiring board (11) and at least the edge sides (6, 7, 8, 9) of the semiconductor chips (3) and the plastic package (14) having an underside (16), which comprises at least the underside (13) of the wiring board (11) with external contact regions (17) and strip-shaped bonding channel coverings (18) arranged in columns for bonding channels (12), and the method having the following method steps:
preparation of a wiring board (11) with semiconductor chip positions arranged in rows (1) and columns (2) and sawing track regions (42) provided in between and also with at least one bonding channel (12), arranged on each semiconductor chip position, and with a constriction (31) for the three-dimensional connection of the upper side (10) and underside (13) of the wiring board (11),
application of semiconductor chips (3) to the semiconductor chip positions, with contact areas (24) of the active upper side (4) of the semiconductor chips (3) being arranged in the region of the bonding channels (12),
establishment of bonding connections (43) between the contact areas (24) and wiring lines on the underside (13) of the wiring board (11) in the region of the bonding channels (12),
simultaneous placement of the upper-side mold (33) and the underside mold (34) of an injection mold, with sealing off of an upper-side cavity (36) for the production of the upper side (15) of the plastic package and underside cavities (38) for the production of bonding channel coverings (18),
injection of package plastic molding compound (25) via an injection hopper (35) of the upper-side mold (33) and spreading of the package plastic molding compound (25) via constrictions (31) into the underside cavities (38).

17. The method as claimed in claim 16, characterized in that the plastic package (14) is removed from the injection mold (32) and the plastic package (14) is separated at the provided sawing tracks (42) into individual electronic components (41).

18. The method as claimed in claim 16 or 17, characterized in that the package plastic molding compound (25) is injected under a pressure of 8 to 15 MPa via an injection-molding hopper (35).
